(19) United States
(12) Patent Application Publication
(10) Pub. No.: US 2025/0157934 A1
(43) Pub. Date: May 15, 2025

(54) SEMICONDUCTOR DEVICES

(71) Applicant: Samsung Electronics Co., Ltd., Suwon-si (KR)

(72) Inventors: Suhyun Bang, Suwon-si (KR); Seulji Song, Suwon-si (KR); Hwayeong Lee, Suwon-si (KR)

(21) Appl. No.: 18/918,467

(22) Filed: Oct. 17, 2024

(30) Foreign Application Priority Data
Nov. 14, 2023 (KR) 10-2023-0157698

(51) Int. Cl. H01L 23/532; H10B 12/00

(52) U.S. Cl. CPC H01L 23/53295; H10B 12/488

(57) ABSTRACT

A semiconductor device includes a bit line above a substrate and extending in a first horizontal direction, a word line at a higher vertical level than the bit line and extending in a second horizontal direction crossing the first horizontal direction, a fluorine-containing insulating layer spaced apart from the word line and extending in the second horizontal direction, and a channel layer between the word line and the fluorine-containing insulating layer, the channel layer including a first side surface and a second side surface opposite to the first side surface. The first side surface faces the word line, and the channel layer includes an oxide semiconductor and fluorine.

### CROSS-REFERENCE TO RELATED APPLICATION

This application is based on and claims priority under 35 U.S.C. § 119 to Korean Patent Application No. 10-2023-0157698, filed on Nov. 14, 2023, in the Korean Intellectual Property Office, the disclosure of which is incorporated by reference herein in its entirety.

### BACKGROUND

The inventive concept relates to a semiconductor device, and more particularly, to a semiconductor device including a vertical channel transistor.

With the downscaling of semiconductor devices, the size of dynamic random access memory (DRAM) devices is also reduced. In a DRAM device having a 1T-1C structure in which one capacitor is connected to one transistor, there is a limitation that the smaller the device becomes, the more current leakage through a channel region increases. To reduce current leakage, vertical channel transistors are proposed which use oxide semiconductor materials as a channel layer.

### SUMMARY

The inventive concept provides a semiconductor device having improved electrical performance.

According to an aspect of the inventive concept, there is provided a semiconductor device including a bit line above a substrate and extending in a first horizontal direction; a word line at a higher vertical level than the bit line and extending in a second horizontal direction crossing the first horizontal direction; a fluorine-containing insulating layer spaced apart from the word line and extending in the second horizontal direction; and a channel layer between the word line and the fluorine-containing insulating layer, the channel layer including a first side surface and a second side surface opposite to the first side surface, wherein the first side surface faces the word line, wherein the channel layer includes an oxide semiconductor and fluorine.

According to another aspect of the inventive concept, there is provided a semiconductor device including a bit line above a substrate and extending in a first horizontal direction; an etch stop film on the bit line; a mold insulating layer on the etch stop film; a word line in a first opening that passes through the mold insulating layer and extends in the first horizontal direction; a channel layer located in a second opening that is adjacent to the word line and passes through the mold insulating layer and the etch stop film; and a fluorine-containing insulating layer spaced apart from the channel layer in a third opening that passes through the mold insulating layer, wherein the third opening extends in the first horizontal direction, wherein the channel layer includes an oxide semiconductor and fluorine.

According to another aspect of the inventive concept, there is provided a semiconductor device including a peripheral circuit region above a substrate; a bit line in the peripheral circuit region and extending in a first horizontal direction; an etch stop film on the bit line; a mold insulating layer on the etch stop film; a word line in a first opening that passes through the mold insulating layer and extends in the first horizontal direction; a channel layer in a second opening that is adjacent to the word line and passes through the mold insulating layer and the etch stop film, the channel layer including an oxide semiconductor and fluorine; a fluorine-containing insulating layer spaced apart from the channel layer in a third opening that passes through the mold insulating layer, wherein the third opening extends in the first horizontal direction; a gate insulating layer in the second opening of the mold insulating layer, a first portion of the gate insulating layer being between the channel layer and the word line and a second portion of the gate insulating layer being between the channel layer and the mold insulating layer; and a storage node above the channel layer.

According to another aspect of the inventive concept, there is a provided a method of manufacturing a semiconductor device, the method including forming a bit line extending in a first horizontal direction; forming a mold stack on the bit line; forming a first opening in the mold stack, the first opening extending in a second horizontal direction crossing the first horizontal direction; forming a word line in the first opening; forming a second opening in the mold stack adjacent to the word line, the second opening extending in the second horizontal direction; forming a channel layer in the second opening; forming a third opening in the mold stack spaced apart from the channel layer and the word line; forming a fluorine-containing insulating layer in the third opening; annealing the semiconductor device such that fluorine included in the fluorine-containing insulating layer diffuses from the fluorine-containing insulating layer to the channel layer.

### BRIEF DESCRIPTION OF THE DRAWINGS

Embodiments will be more clearly understood from the following detailed description taken in conjunction with the accompanying drawings in which:

FIG. 1 is a layout view illustrating a semiconductor device according to embodiments;

FIG. 2 is an enlarged layout view of a portion of a cell array region of FIG. 1;

FIG. 3 is a cross-sectional view taken along line A1-A1′ of FIG. 2;

FIG. 4 is a cross-sectional view taken along line A2-A2′ of FIG. 2;

FIG. 5 is an enlarged view of region B of FIG. 3;

FIGS. 6 and 7 are cross-sectional views illustrating a semiconductor device according to embodiments;

FIG. 8 is an enlarged view of region B of FIG. 6;

FIGS. 9 and 10 are cross-sectional views illustrating a semiconductor device according to embodiments;

FIGS. 11A, 11B, 12A, 12B, 13A, 13B, 14A, 14B, 15A, 15B, 16, 17A, 17B, 18A, 18B, 19A, 19B, 20A, 20B, 20C, and 21 are schematic views illustrating a method of manufacturing a semiconductor device according to embodiments; FIGS. 11B, 12B, 13B, 14B, 15B, 16, 17B, 18B, 19A, 20B, and 21 are cross-sectional views taken along line A1-A1′ of FIG. 2, FIGS. 11A, 12A, 13A, 14A, 15A, 17A, 18A, and 20A are top views of FIGS. 11B, 12B, 13B, 14B, 15B, 17B, 18B, and 20B, respectively, FIG. 20C is a cross-sectional view taken along line A2-A2′ of FIG. 2, and FIG. 19B is an enlarged view of region B of FIG. 19A; and

FIGS. 22A, 22B, and 23 are schematic views illustrating a method of manufacturing a semiconductor device according to embodiments.

FIG. 24 shows a method of manufacturing a semiconductor device according to embodiments.

### DETAILED DESCRIPTION OF THE EMBODIMENTS

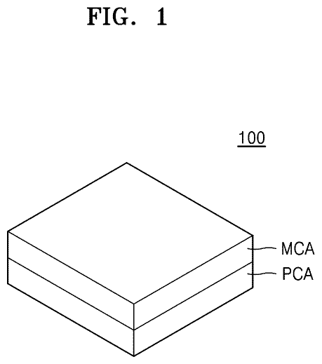

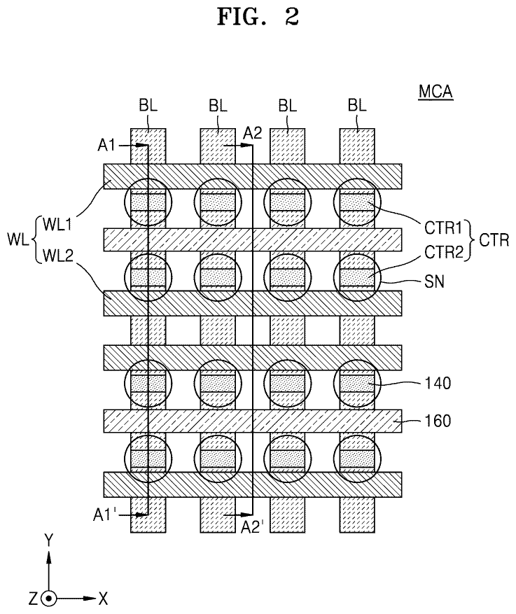

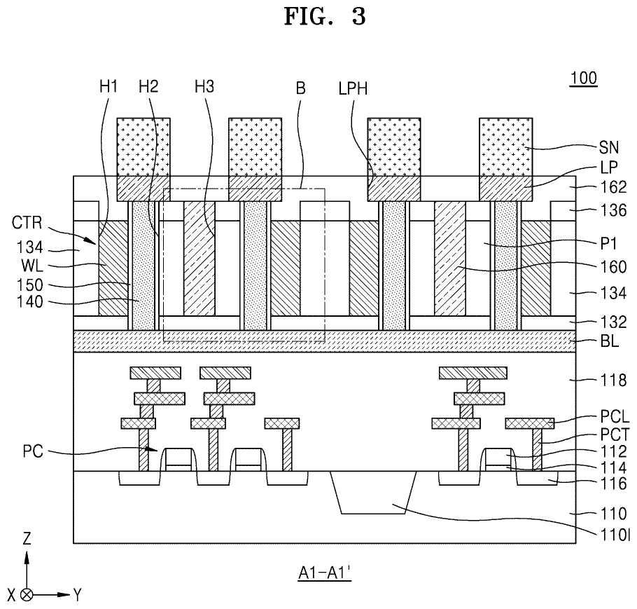

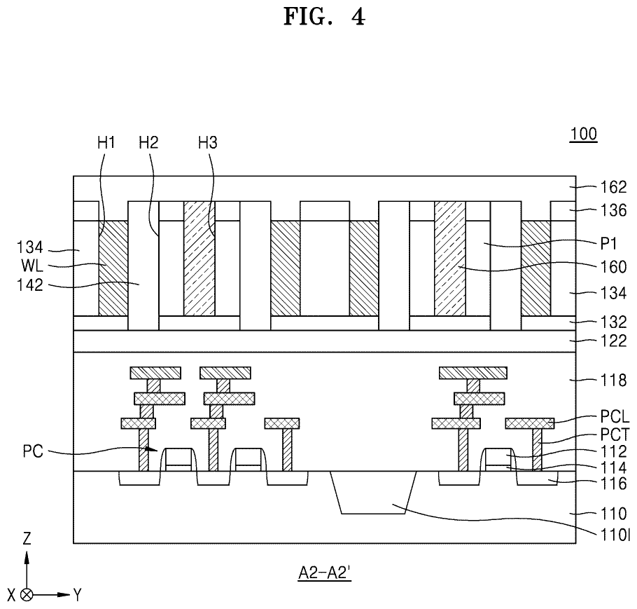

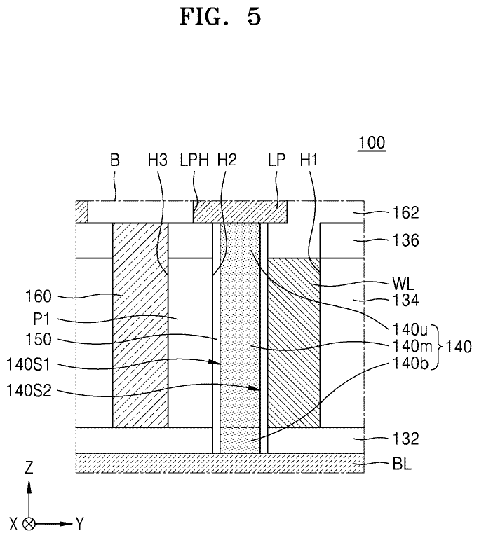

FIG. 1 is a layout view illustrating a semiconductor device 100 according to embodiments. FIG. 2 is an enlarged layout view of a portion of a cell array region MCA of FIG. 1. FIG. 3 is a cross-sectional view taken along line A1-A1′ of FIG. 2. FIG. 4 is a cross-sectional view taken along line A2-A2′ of FIG. 2. FIG. 5 is an enlarged view of region B of FIG. 3.

Referring to FIGS. 1 to 5, the semiconductor device 100 may include a peripheral circuit region PCA and a cell array region MCA located at a higher vertical level than the peripheral circuit region PCA.

In some embodiments, the cell array region MCA may include a memory cell region of a dynamic random access memory (DRAM) device, and the peripheral circuit region PCA may include a core region or a peripheral circuit region of a DRAM device. For example, the peripheral circuit region PCA may include a peripheral circuit transistor PC for transmitting a signal and/or power to a memory cell array included in the cell array region MCA. In some embodiments, the peripheral circuit transistor PC may constitute various circuits such as a command decoder, control logic, address buffer, row decoder, column decoder, sense amplifier, and data input/output circuit.

As illustrated in FIG. 2, in the cell array region MCA, a plurality of word lines WL extending in a first horizontal direction X and a plurality of bit lines BL extending in a second horizontal direction Y may be located. A plurality of cell transistors CTR may be located at intersections between the plurality of word lines WL and the plurality of bit lines BL. A plurality of storage nodes SN may be respectively located above the plurality of cell transistors CTR.

The plurality of word lines WL may include a first word line WL1 and a second word line WL2 that are alternately arranged in the second horizontal direction Y, and the plurality of cell transistors CTR may include a first cell transistor CTR1 and a second cell transistor CTR2 that are alternately arranged in the second horizontal direction Y. The first cell transistor CTR1 may be located adjacent to the first word line WL1, and the second cell transistor CTR2 may be located adjacent to the second word line WL2.

The first cell transistor CTR1 and the second cell transistor CTR2 may have a mirror symmetric structure with respect to each other. For example, the first cell transistor CTR1 and the second cell transistor CTR2 may have a mirror symmetric structure with respect to a center line, extending in the first horizontal direction X, between the first cell transistor CTR1 and the second cell transistor CTR2.

In some embodiments, the plurality of word lines WL may have a width of 1F, the plurality of word lines WL may have a pitch (i.e. the sum of a width and an interval) of 2F, the plurality of bit lines BL may have a width of 1F, the plurality of bit lines BL may have a pitch (i.e. the sum of a width and an interval) of 2F, and a unit area for forming one cell transistor CTR may be 4F². Therefore, the cell transistor CTR may be of a crosspoint type requiring a relatively small unit area, which may be advantageous in improving the degree of integration of the semiconductor device 100.

A substrate 110 may be formed of or include silicon, for example, single crystalline silicon, polycrystalline silicon, or amorphous silicon. In some embodiments, the substrate 110 may include at least one selected from among Ge, SiGe, SiC, GaAs, InAs, and InP. In some embodiments, the substrate 110 may include a conductive region, for example, a well doped with impurities or a structure doped with impurities.

A device isolation layer 1101 defining an active region may be located on the substrate 110, and peripheral circuit transistors PC may be located on the substrate 110. Each of the peripheral circuit transistors PC may include a gate electrode 112, a gate insulating layer 114, and source/drain regions 116, and may be electrically connected to the bit line BL or the word line WL through, for example, peripheral circuit wires PCL and peripheral circuit contacts PCT.

On the substrate 110, a peripheral circuit insulating layer 118 may cover the peripheral circuit transistors PC, peripheral circuit wires PCL, and peripheral circuit contacts PCT. The peripheral circuit insulating layer 118 may be formed of or include an oxide film, a nitride film, a low-k dielectric film, or a combination thereof and may have a laminated structure of a plurality of insulating layers.

The bit line BL extending in the second horizontal direction Y may be located on the peripheral circuit insulating layer 118. In some embodiments, the bit line BL may be formed of or include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof.

A bit line separation insulating layer 122 may be located between the plurality of bit lines BL (see, e.g., FIG. 4). The bit line separation insulating layer 122 may be formed of or include an oxide film, a nitride film, a low-k dielectric film, or a combination thereof.

In some embodiments, a shielding structure extending in the second horizontal direction Y may be further located between the plurality of bit lines BL. The shielding structure may be formed of or include a conductive material, such as metal. In some embodiments, the shielding structure may be formed of a conductive material and may include an air gap or a void therein, or, in other embodiments, air gaps may be defined in the bit line separation insulating layer 122 instead of the shielding structure.

An etch stop film 132 may be located on the bit line BL and the bit line separation insulating layer 122, and a mold insulating layer 134 may be located on the etch stop film 132. The etch stop film 132 may be formed of or include silicon nitride, and the mold insulating layer 134 may be formed of or include silicon oxide. The mold insulating layer 134 may include a first opening H1, a second opening H2, and a third opening H3 that pass through the mold insulating layer 134. The first opening H1 may pass through the mold insulating layer 134 and extend in the first horizontal direction X, and the second opening H2 may be located in communication with the first opening H1 and may pass through the etch stop film 132, thereby exposing an upper surface of the bit line BL at the bottom portion of the second opening H2. The third opening H3 may pass through the mold insulating layer 134 and extend in the first horizontal direction X and may be spaced apart from the first opening H1 and the second opening H2.

As used herein, a first opening being “in communication with” a second opening may mean that the first opening and the second opening would be contiguous portions of a larger opening if they were present at the same time. However, the phrase “in communication with” does not require that the openings are present at the same time. For example, the first opening may be formed and filled with one or more elements before the second opening is formed at a position adjacent to the location of the one or more elements that fill the first opening.

In some embodiments, a cover insulating layer 136 may be located on the mold insulating layer 134. The cover insulating layer 136 may be formed of or include silicon nitride. In these embodiments, the first opening H1, the second opening H2, and the third opening H3 may pass through the cover insulating layer 136 and extend in a vertical direction Z.

The word line WL may be located in the first opening H1 of the mold insulating layer 134. The word line WL may have one side wall that is in contact with the mold insulating layer 134, and the word line WL may have a bottom surface that is located on the etch stop film 132. As illustrated in FIG. 3, the word line WL may have an upper surface that is at the same level of an upper surface of the mold insulating layer 134, or, in some embodiments, the upper surface of the word line WL may be at a lower level than the upper surface of the mold insulating layer 134. In some embodiments, the word line WL may be formed of or include Ti, TiN, Ta, TaN, Mo, Ru, W, WN, TiSiN, WSiN, polysilicon, or a combination thereof.

A channel layer 140 may be located in the second opening H2 of the mold insulating layer 134. The channel layer 140 may extend in the vertical direction Z within the second opening H2, and the channel layer 140 may have a bottom surface that is placed on the upper surface of the bit line BL. For example, the second opening H2 may extend in the first horizontal direction X, and the channel layer 140 may be located on the upper surface of the bit line BL within the second opening H2. For example, the channel layer 140 may be formed in plurality, with one channel layer 140 located on an upper surface of one bit line BL within the second opening H2 and another channel layer 140 located on an upper surface of another bit line BL adjacent to the one bit line BL within the second opening H2.

In some embodiments, the channel layer 140 may be formed of or include an oxide semiconductor material including fluorine. In some embodiments, the oxide semiconductor material may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O). For example, the channel layer 140 may include an oxide semiconductor material including fluorine, wherein a content (e.g., an amount) of fluorine may range from about 0.1 atomic percent (at %) to about 6 at %.

With reference to FIG. 5, for example, in some embodiments, the channel layer 140 may include a bottom portion 140b, an upper portion 140u, and a main region 140m. The main region 140m of the channel layer 140 may have a greater content of fluorine than the bottom portion 140b of the channel layer 140 or the upper portion 140u of the channel layer 140. For example, the main region 140m of the channel layer 140 may refer to a portion of the channel layer 140 in which fluorine has been diffused and/or moved by an annealing process from a fluorine-containing insulating layer 160 through a first portion P1 of the mold insulating layer 134 into the channel layer 140. The main region 140m of the channel layer 140 may function as a vertical channel for the cell transistor CTR.

In some embodiments, the bottom portion 140b of the channel layer 140 and the upper portion 140u of the channel layer 140 may be further doped with impurity ions and the bottom portion 140b of the channel layer 140 and the upper portion 140u of the channel layer 140 may function as a source contact and a drain contact, respectively.

With reference to FIG. 3, for example, in some embodiments, a first portion of the mold insulating layer 134 may be between the channel layer 140 and the fluorine-containing insulating layer 160 described below. In some embodiments, a second portion of the mold insulating layer 134 may be on a side wall of the word line WL.

Within the second opening H2 of the mold insulating layer 134, a gate insulating layer 150 may be located on both side walls of the channel layer 140. The gate insulating layer 150 may be disposed between the channel layer 140 and the word line WL and may be disposed between the channel layer 140 and the mold insulating layer 134.

With reference to FIG. 5, for example, in some embodiments, a first portion of the gate insulating layer 150 may be between a first side surface of the channel layer 140 and the word line WL. In some embodiments, a second portion of the gate insulating layer 150 may be between a second side surface of the channel layer 140 and the mold insulating layer 134.

In some embodiments, the gate insulating layer 150 may be formed of or include at least one selected from among high-k dielectric materials and ferroelectric materials that have a higher dielectric constant than silicon oxide. In some embodiments, the gate insulating layer 150 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (StTaBiO), bismuth iron oxide (BiFeO), strontium titanium oxide (SrTiO), yttrium oxide (YO), aluminum oxide (AlO), and lead scandium tantalum oxide (PbScTaO).

A buried insulating layer 142 may be located between two adjacent channel layers 140 within the second opening H2 of the mold insulating layer 134. For example, the buried insulating layer 142 may be located in the second opening H2 at a position that vertically overlaps the bit line separation insulating layer 122. In some embodiments, as illustrated in FIG. 4, the buried insulating layer 142 may be located in direct contact with a side wall of the word line WL and a side wall of the mold insulating layer 134, and the gate insulating layer 150 may not be disposed between the buried insulating layer 142 and the word line WL and between the buried insulating layer 142 and the mold insulating layer 134. However, in other embodiments, the gate insulating layer 150 may be located to extend on the entire second opening H2, and, in this case, the gate insulating layer 150 may be disposed between the buried insulating layer 142 and the word line WL and between the buried insulating layer 142 and the mold insulating layer 134.

The fluorine-containing insulating layer 160 may be located in the third opening H3 of the mold insulating layer 134. The fluorine-containing insulating layer 160 may be formed of or include silicon nitride in which fluorine is contained. For example, the fluorine-containing insulating layer 160 may extend in the first horizontal direction X and the fluorine-containing insulating layer 160 may have a bottom surface that is in contact with an upper surface of the etch stop film 132. In some embodiments, the fluorine-containing insulating layer 160 may have an upper surface that is at the same level of an upper surface of the cover insulating layer 136.

As illustrated in FIG. 2, the fluorine-containing insulating layer 160 may be disposed between the first word line WL1 and the second word line WL2, the first cell transistor CTR1 may be disposed between the fluorine-containing insulating layer 160 and the first word line WL1, and the second cell transistor CTR2 may be disposed between the fluorine-containing insulating layer 160 and the second word line WL2.

The fluorine-containing insulating layer 160 may be spaced apart from the channel layer 140 with the first portion P1 of the mold insulating layer 134 therebetween. In some embodiments, the first portion P1 of the mold insulating layer 134 may include fluorine. For example, in an annealing process for diffusing fluorine atoms included in the fluorine-containing insulating layer 160 into the channel layer 140, the fluorine atoms may remain in the first portion P1 of the mold insulating layer 134. A fluorine content in the fluorine-containing insulating layer 160 may be a first content, a fluorine content in the channel layer 140 may be a second content, and a fluorine content in the first portion P1 of the mold insulating layer 134 may be a third content, wherein the first content may be greater than the second content, and the first content may be greater than the third content.

An upper insulating layer 162 may be located on the cover insulating layer 136. A landing pad LP may be located in a landing pad opening LPH passing through the upper insulating layer 162. The landing pad LP may be in contact with an upper surface of the channel layer 140. In some embodiments, the landing pad LP may be formed of or include Ti, TiN, Ta, TaN, W, WN, TiSiN, WSiN, polysilicon, or a combination thereof.

The storage node SN may be located on the landing pad LP. In some embodiments, the storage node SN may include a capacitor having a metal-insulator-metal (MIM) structure. In other embodiments, the storage node SN may include a variable resistance memory component, a phase change memory component, a magnetic memory component, and the like.

According to the embodiments described above, the channel layer 140 may be formed of or include an oxide semiconductor in which fluorine is contained, and fluorine included in the channel layer 140 may be formed by diffusing/moving the fluorine atoms included in the fluorine-containing insulating layer 160 into the channel layer 140 through an annealing process. As the channel layer 140 includes the oxide semiconductor in which fluorine is contained, for example, an oxide semiconductor such as indium gallium zinc oxide containing fluorine, fluorine ions may bind to oxygen vacancies within the channel layer 140 and trap density within the channel layer 140 may decrease. Alternatively, as some oxygen atoms of the oxide semiconductor forming the channel layer 140 are replaced with fluorine atoms, channel mobility may increase. Alternatively, as a portion of a relatively weak bonding of zinc atoms and oxygen atoms of the channel layer 140 is replaced with a relatively strong bonding of zinc atoms and fluorine atoms, material stability of the channel layer 140 may improve. Therefore, electrical performance of the cell transistor CTR including the oxide semiconductor in which fluorine is contained as a composition of the channel layer 140 may improve.

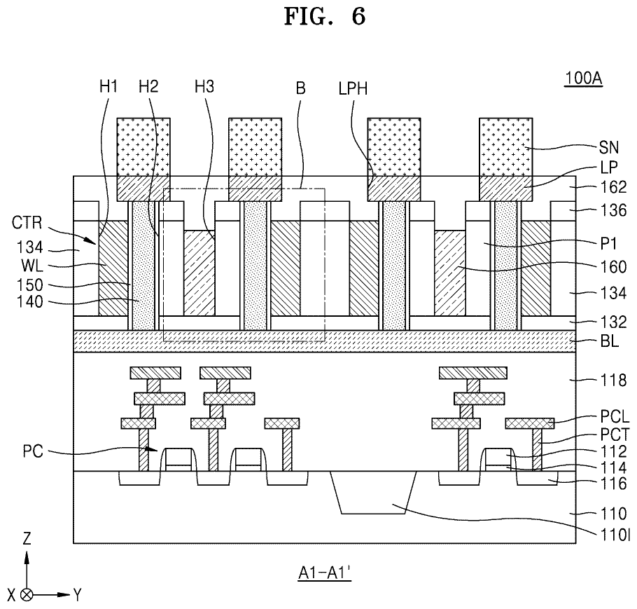

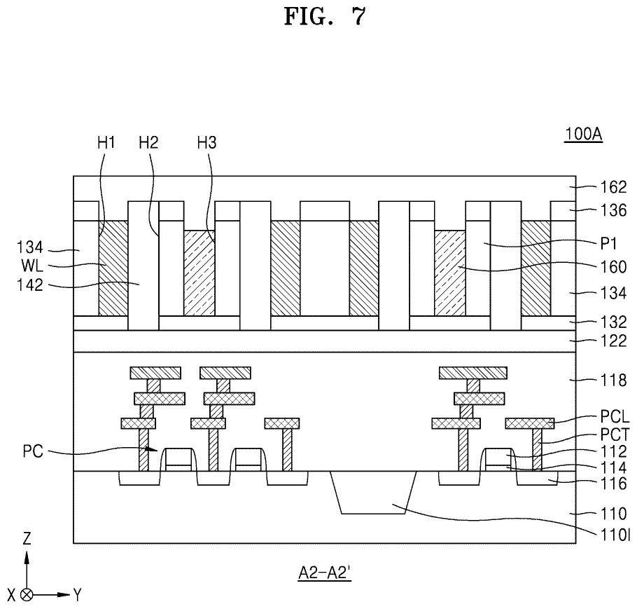

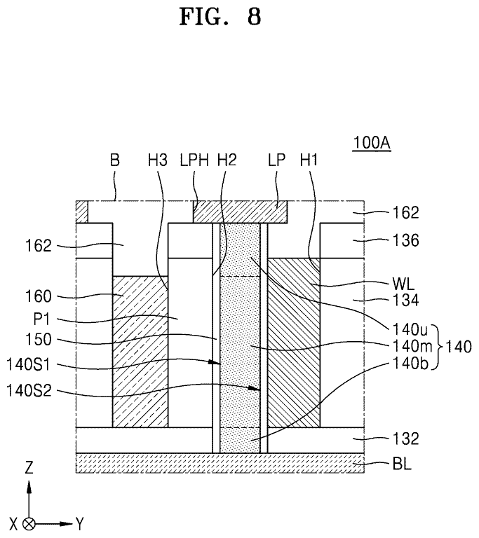

FIGS. 6 and 7 are cross-sectional views illustrating a semiconductor device 100a according to embodiments. FIG. 8 is an enlarged view of region B of FIG. 6.

Referring to FIGS. 6 to 8, a fluorine-containing insulating layer 160 may have an upper surface that is at a lower level than an upper surface of a cover insulating layer 136 and at a lower level than an upper surface of a mold insulating layer 134.

In some embodiments, a channel layer 140 may include a bottom portion 140b, an upper portion 140u, and a main region 140m. The main region 140m of the channel layer 140 may have a greater content of fluorine than the bottom portion 140b of the channel layer 140 or the upper portion 140u of the channel layer 140. A boundary between the main region 140m of the channel layer 140 and the upper portion 140u of the channel layer 140 may be at the same level as the upper surface of the fluorine-containing insulating layer 160.

For example, the main region 140m of the channel layer 140 may refer to a portion of the channel layer 140 in which fluorine has been diffused and/or moved by an annealing process from the fluorine-containing insulating layer 160 through a first portion P1 of the mold insulating layer 134 into the channel layer 140. The main region 140m of the channel layer 140 may function as a vertical channel for a cell transistor CTR.

In some embodiments, the bottom portion 140b of the channel layer 140 and the upper portion 140u of the channel layer 140 may be further doped with impurity ions, and the bottom portion 140b of the channel layer 140 and the upper portion 140u of the channel layer 140 may function as a source contact and a drain contact, respectively.

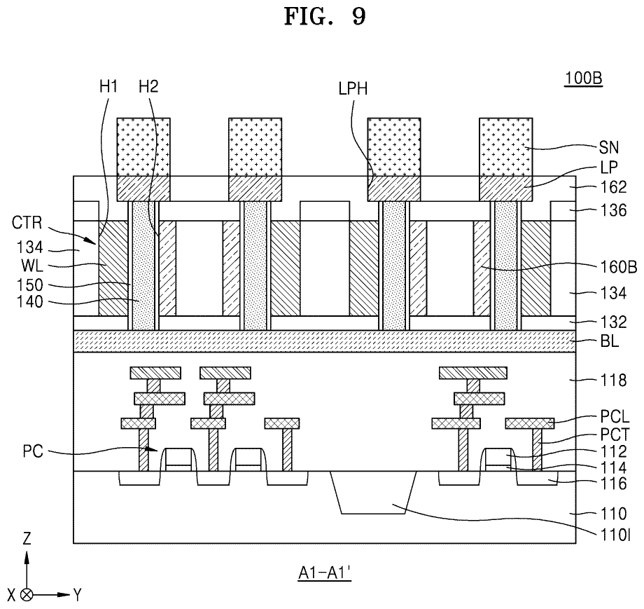

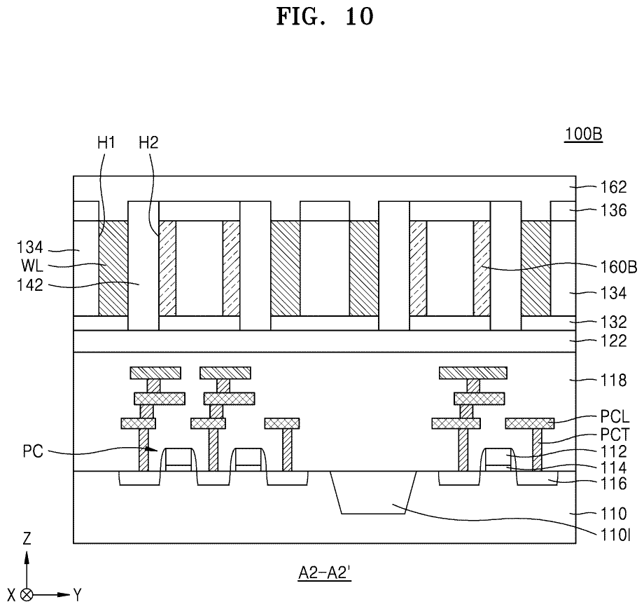

FIGS. 9 and 10 are cross-sectional views illustrating a semiconductor device 100B according to embodiments. In FIGS. 9 and 10, the same reference numerals as FIGS. 1 to 8 refer to the same components.

Referring to FIGS. 9 and 10, a fluorine-containing insulating layer 160B may extend in the first horizontal direction X between the channel layer 140 and the mold insulating layer 134. The fluorine-containing insulating layer 160B may be in contact with the gate insulating layer 150 and the buried insulating layer 142. The cover insulating layer 136 may be located on an upper surface of the fluorine-containing insulating layer 160B.

In some embodiments, the fluorine-containing insulating layer 160B may be formed of or include silicon oxide in which fluorine is contained. In some embodiments, the fluorine-containing insulating layer 160B may be formed as fluorine-containing etchants diffuse into an inner region of the mold insulating layer 134 adjacent to the second opening H2 in an etching process for forming the second opening H2 by removing a portion of the mold insulating layer 134.

The channel layer 140 may be formed of or include an oxide semiconductor in which fluorine is contained and, according to the embodiments described above, the channel layer 140 may include the oxide semiconductor in which fluorine is contained, and fluorine included in the channel layer 140 may be formed by diffusing/moving the fluorine atoms included in the fluorine-containing insulating layer 160B into the channel layer 140 through an annealing process.

As the channel layer 140 includes the oxide semiconductor in which fluorine is contained, for example, an oxide semiconductor such as indium gallium zinc oxide containing fluorine, fluorine ions may bind to oxygen vacancies within the channel layer 140 and trap density within the channel layer 140 may decrease. Alternatively, as some oxygen atoms of the oxide semiconductor forming the channel layer 140 are replaced with fluorine atoms, channel mobility may increase. Alternatively, as a portion of a relatively weak bonding of zinc atoms and oxygen atoms of the channel layer 140 is replaced with a relatively strong bonding of zinc atoms and fluorine atoms, material stability of the channel layer 140 may improve. Therefore, electrical performance of the cell transistor CTR including the oxide semiconductor in which fluorine is contained as a composition of the channel layer 140 may improve.

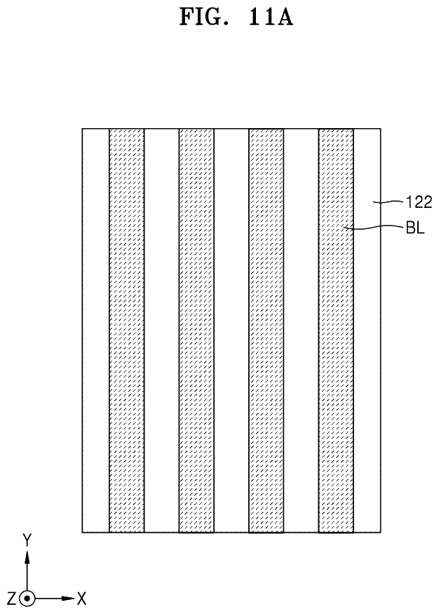

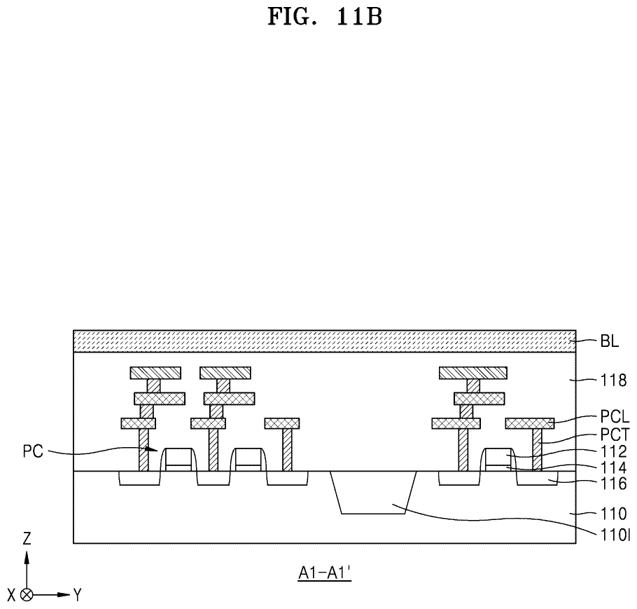

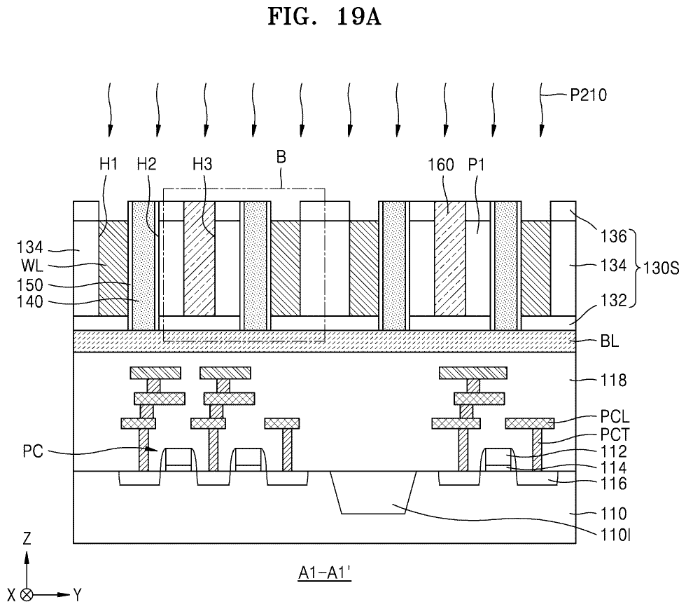

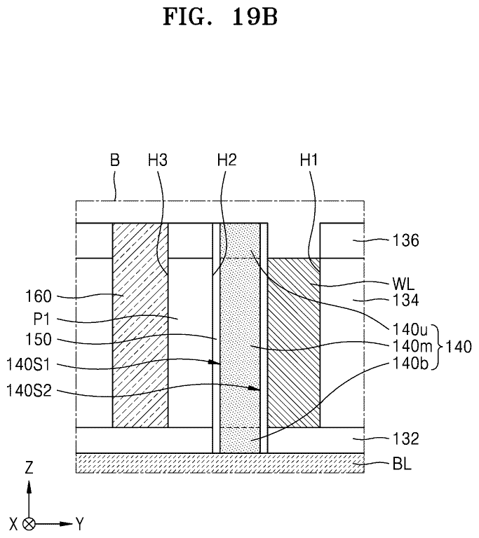

FIGS. 11A, 11B, 12A, 12B, 13A, 13B, 14A, 14B, 15A, 15B, 16, 17A, 17B, 18A, 18B, 19A, 19B, 20A, 20B, 20C, and 21 are schematic views illustrating a method of manufacturing a semiconductor device 100, according to embodiments. FIGS. 11B, 12B, 13B, 14B, 15B, 16, 17B, 18B, 19A, 20B, and 21 are cross-sectional views taken along line A1-A1′ of FIG. 2, FIGS. 11A, 12A, 13A, 14A, 15A, 17A, 18A, and 20A are top views of FIGS. 11B, 12B, 13B, 14B, 15B, 17B, 18B, and 20B, respectively, and FIG. 19B is an enlarged view of region B of FIG. 19A.

Referring to FIGS. 11A and 11B, peripheral circuit transistors PC, peripheral circuit wires PCL, peripheral circuit contacts PCT, and a peripheral circuit insulating layer 118 may be formed above a substrate 110. Each of the peripheral circuit transistors PC may include a gate electrode 112, a gate insulating layer 114, and source/drain regions 116. On the substrate 110, the peripheral circuit insulating layer 118 may cover the peripheral circuit transistors PC, the peripheral circuit wires PCL, and the peripheral circuit contacts PCT.

After that, on the peripheral circuit insulating layer 118, a plurality of bit lines BL extending in a second horizontal direction Y and a bit line separation insulating layer 122 filling a space between the plurality of bit lines BL may be formed.

In some embodiments, the bit line separation insulating layer 122 may be formed on the peripheral circuit insulating layer 118, a bit line formation space (not shown) may be formed by patterning the bit line separation insulating layer 122 with a mask pattern (not shown), a conductive layer may be formed in the bit line formation space, and an upper portion of the conductive layer may be removed so that an upper surface of the bit line separation insulating layer 122 may be exposed, thereby allowing the plurality of bit lines BL to be formed.

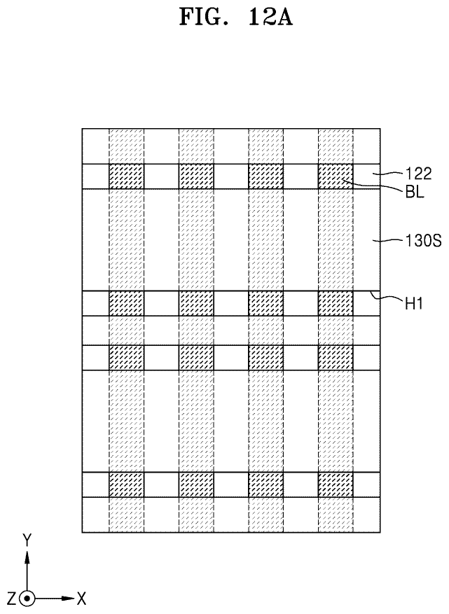

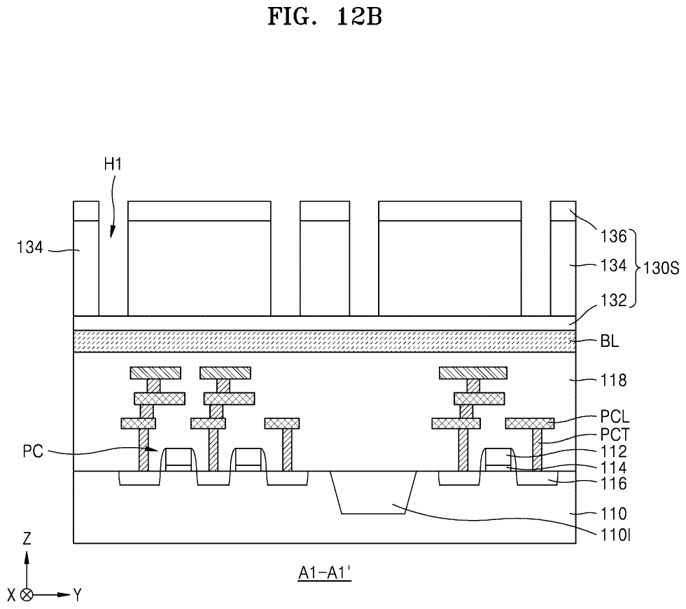

Referring to FIGS. 12A and 12B, a mold stack 130S may be formed on the plurality of bit lines BL and the bit line separation insulating layer 122.

The mold stack 130S may include an etch stop film 132, a mold insulating layer 134, and a cover insulating layer 136. For example, the etch stop film 132 may be formed with silicon nitride, the mold insulating layer 134 may be formed with silicon oxide, and the cover insulating layer 136 may be formed with silicon nitride.

After that, a mask pattern (not shown) may be formed on the mold stack 130S, and a first opening H1 may be formed using the mask pattern as an etching mask. The first opening H1 may pass through the mold insulating layer 134 and the cover insulating layer 136 and may not pass through the etch stop film 132, and the first opening H1 may have a bottom portion exposing an upper surface of the etch stop film 132. In FIG. 12A, for ease of understanding, it is illustrated that an upper surface of the bit line BL and an upper surface of the bit line separation insulating layer 122 are at the bottom portion of the first opening H1, with the etch stop film 132 omitted.

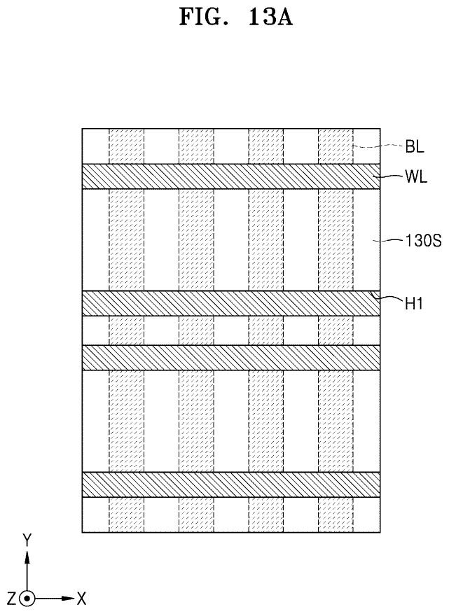

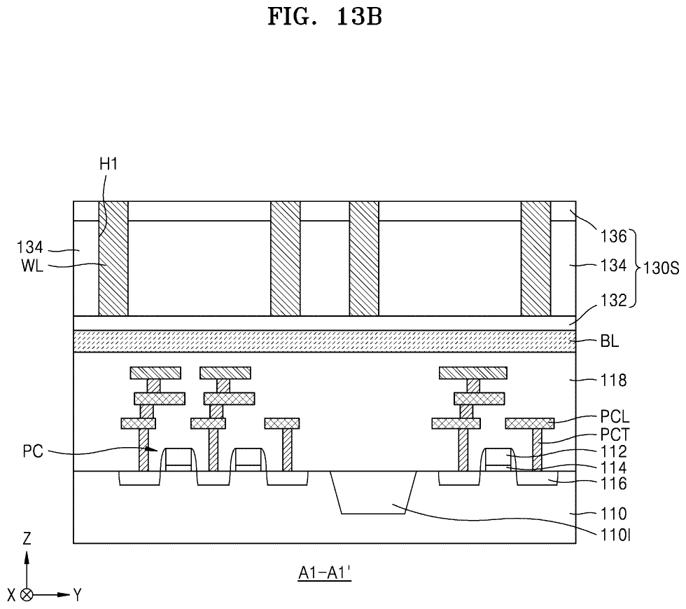

Referring to FIGS. 13A and 13B, a word line WL may be formed in the first opening H1 with conductive materials. In some embodiments, the word line WL may be formed of or include Ti, TiN, Ta, TaN, Mo, Ru, W, WN, TiSiN, WSiN, polysilicon, or a combination thereof.

The word line WL may have an upper surface that is at the same level of an upper surface of the cover insulating layer 136. In addition, the word line WL may be electrically insulated from the bit line BL due to the etch stop film 132.

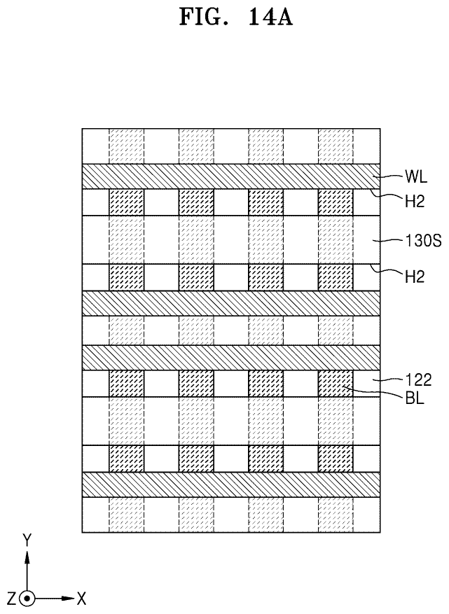

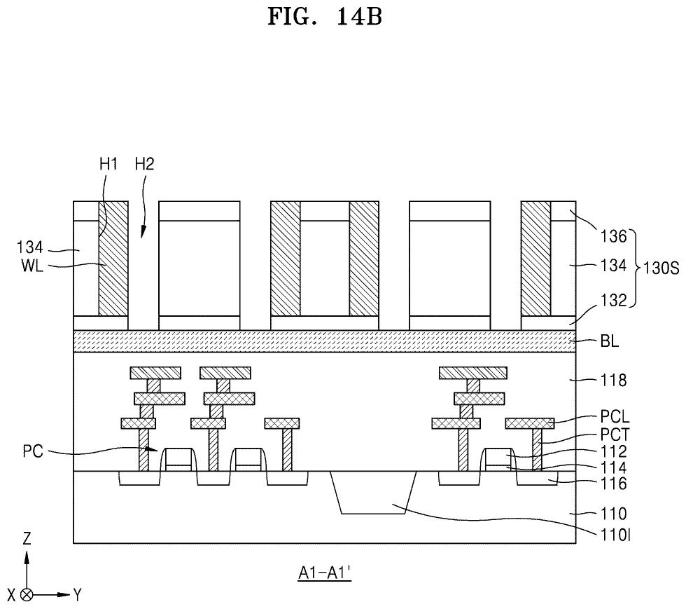

Referring to FIGS. 14A and 14B, a mask pattern (not shown) may be formed on the mold stack 130S, and a second opening H2 may be formed using the mask pattern as an etching mask. The second opening H2 may pass through all of the cover insulating layer 136, the mold insulating layer 134, and the etch stop film 132, and the second opening H2 may have a bottom portion exposing the upper surface of the bit line BL and the upper surface of the bit line separation insulating layer 122.

In some embodiments, the second opening H2 may be formed to communicate with the first opening H1, and the second opening H2 may be formed to expose a side wall of the word line WL and extend in the first horizontal direction X. Accordingly, a first side wall of the second opening H2 may expose the word line WL, and a second side wall of the second opening H2 may expose the mold stack 130S (e.g., the etch stop film 132, the mold insulating layer 134, and the cover insulating layer 136).

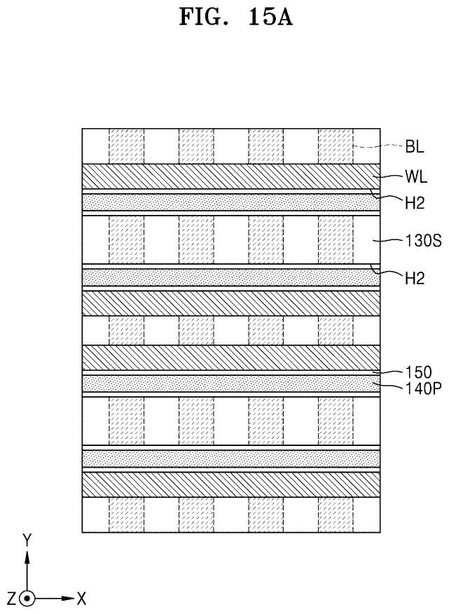

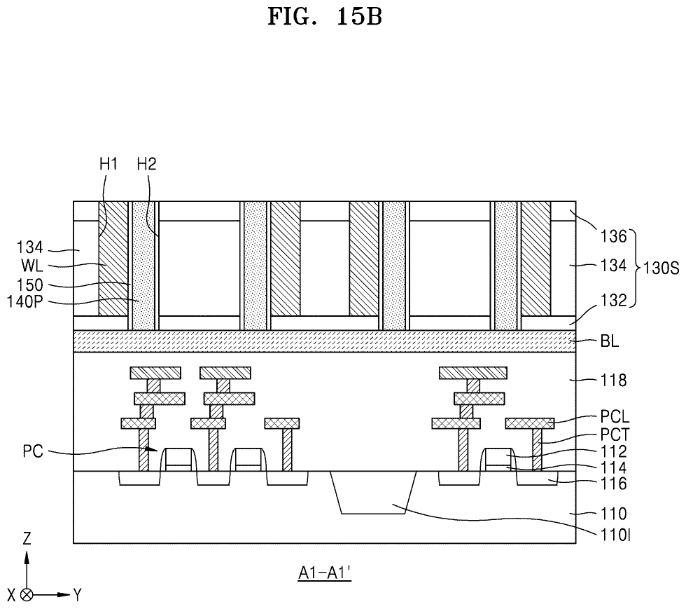

Referring to FIGS. 15A and 15B, a gate insulating layer 150 may be formed on the side wall of the second opening H2 of the mold stack 130S, and, after that, a preliminary channel layer 140P filling the second opening H2 may be formed on the gate insulating layer 150. In some embodiments, in a process of forming the gate insulating layer 150, the gate insulating layer 150 may be formed on the side wall and the bottom portion of the second opening H2, and, after that, an etch back process for removing a portion of the gate insulating layer 150 located on the bit line BL and the bit line separation insulating layer 122 may be further performed, thereby leaving the gate insulating layer 150 on the side wall of the second opening H2.

In some embodiments, the preliminary channel layer 140P may be formed with oxide semiconductor materials. For example, the preliminary channel layer 140P may be formed of or include at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), and tin oxide (SnₓO).

In some embodiments, the preliminary channel layer 140P may be formed using at least one of a chemical vapor deposition (CVD) process, a low pressure CVD process, a plasma-enhanced CVD process, an metal-organic CVD (MOCVD) process, and an atomic layer deposition process.

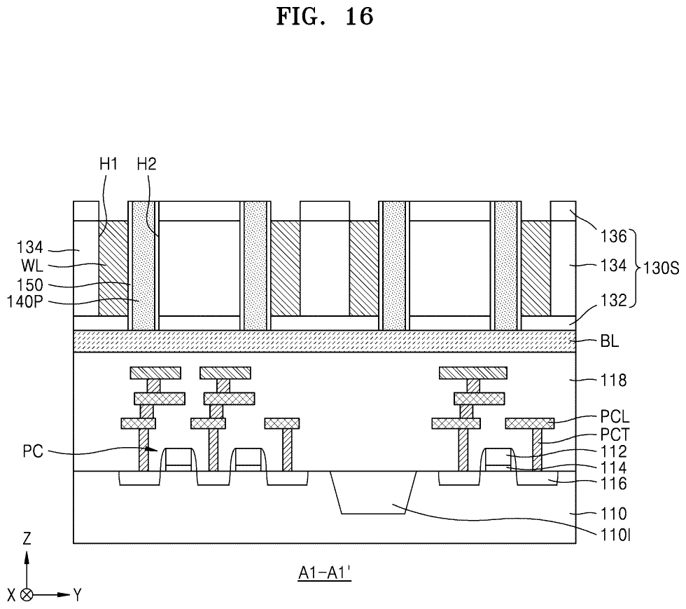

Referring to FIG. 16, a recess process for removing an upper portion of the word line WL may be performed. As the upper portion of the word line WL has been removed, the upper surface of the word line WL may be at a lower level than an upper surface of the mold stack 130S (e.g., the upper surface of the cover insulating layer 136).

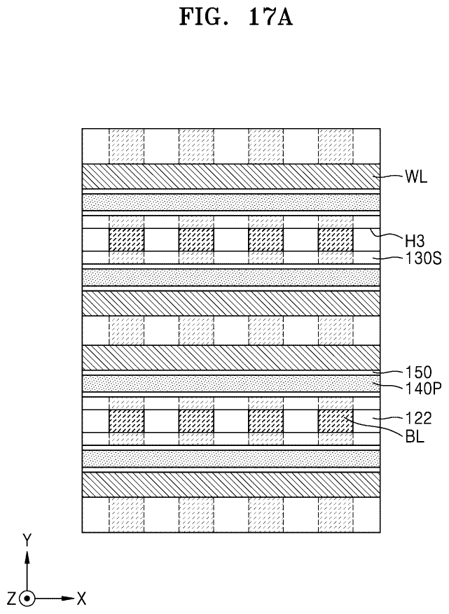

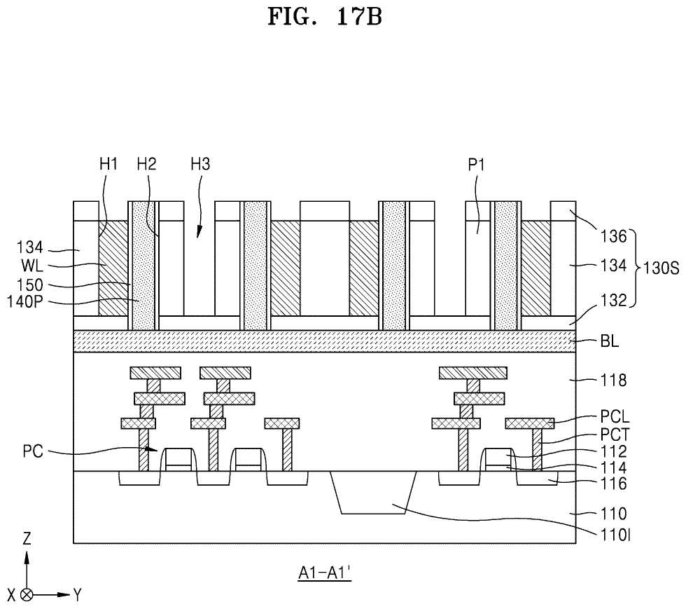

Referring to FIGS. 17A and 17B, a mask pattern (not shown) may be formed on the mold stack 130S, and a third opening H3 may be formed using the mask pattern as an etching mask. The third opening H3 may pass through the mold insulating layer 134 and the cover insulating layer 136 and may not pass through the etch stop film 132, and the third opening H3 may have a bottom portion exposing the upper surface of the etch stop film 132. In FIG. 17A, for ease of understanding, it is illustrated that the upper surface of the bit line BL and the upper surface of the bit line separation insulating layer 122 are at the bottom portion of the third opening H3, with the etch stop film 132 omitted.

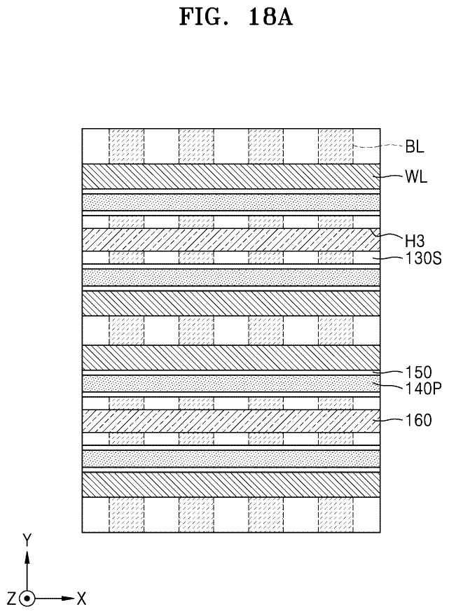

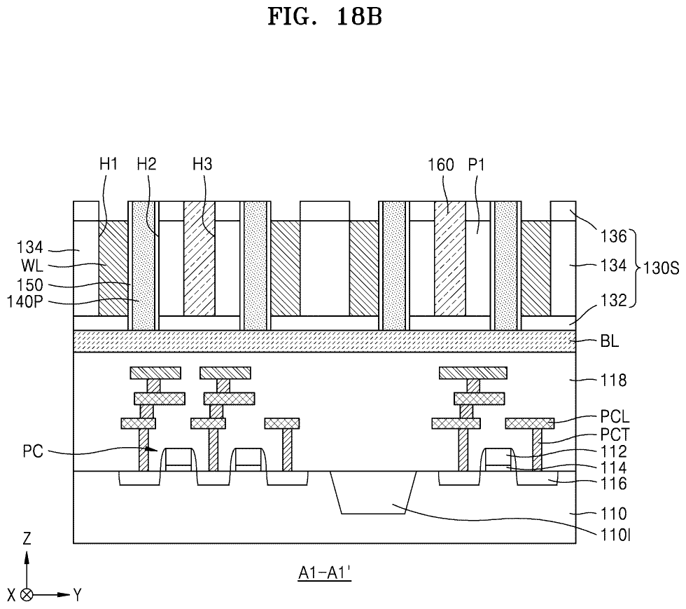

Referring to FIGS. 18A and 18B, a fluorine-containing insulating layer 160 may be formed in the third opening H3.

In some embodiments, the fluorine-containing insulating layer 160 may be formed of or include silicon nitride in which fluorine is contained. In some embodiments, the fluorine-containing insulating layer 160 may be formed using at least one of a chemical vapor deposition (CVD) process, a low pressure CVD process, a plasma-enhanced CVD process, a metal-organic CVD (MOCVD) process, and an atomic layer deposition process. For example, the fluorine-containing insulating layer 160 may be formed to include fluorine with the first content.

In some embodiments, the fluorine-containing insulating layer 160 may be formed by supplying fluorine-containing precursors at a predetermined flow rate in a formation process of silicon nitride using the chemical vapor deposition (CVD) process. In some embodiments, the fluorine-containing precursors may include ammonium fluoride (NH₄F) or ammonium hydrofluoride (NH₅F₂), but are not limited thereto.

Referring to FIGS. 19A and 19B, an annealing process P210 may be performed.

In some embodiments, the annealing process P210 may be performed at a temperature of about 100° C. to about 400° C. for several minutes to several hours. In some embodiments, the annealing process P210 may be performed at atmospheric pressure or under reduced pressure. In some embodiments, by the annealing process P210, fluorine atoms contained in the fluorine-containing insulating layer 160 may diffuse and move into the preliminary channel layer 140P through the mold insulating layer 134.

A channel layer 140 may be formed as fluorine atoms diffuse into the preliminary channel layer 140P by the annealing process P210. The channel layer 140 may include an upper portion 140u, a bottom portion 140b, and a main region 140m, and the main region 140m may refer to a portion of the channel layer 140 facing the mold insulating layer 134 with the gate insulating layer 150 therebetween. The fluorine atoms contained in the fluorine-containing insulating layer 160 may diffuse and move into the main region 140m through the mold insulating layer 134, and, in some embodiments, a content of fluorine in the main region 140m may be greater than contents of fluorine in the upper portion 140u and the bottom portion 140b.

According to some embodiments, as the channel layer 140 includes an oxide semiconductor in which fluorine is contained, for example, an oxide semiconductor such as indium gallium zinc oxide containing fluorine, fluorine ions may bind to oxygen vacancies within the channel layer 140 and trap density within the channel layer 140 may decrease. Alternatively, as some oxygen atoms of the oxide semiconductor forming the channel layer 140 are replaced with fluorine atoms, channel mobility may increase. Alternatively, as a portion of a relatively weak bonding of zinc atoms and oxygen atoms of the channel layer 140 is replaced with a relatively strong bonding of zinc atoms and fluorine atoms, material stability of the channel layer 140 may improve.

By the annealing process P210, the fluorine atoms may diffuse into a first portion P1 of the mold insulating layer 134 located between the channel layer 140 and the fluorine-containing insulating layer 160, and, accordingly, the first portion P1 of the mold insulating layer 134 may be formed of or include silicon oxide in which fluorine is contained.

In some embodiments, a fluorine content in the fluorine-containing insulating layer 160 may be a first content, a fluorine content in the channel layer 140 may be a second content, and a fluorine content in the first portion P1 of the mold insulating layer 134 may be a third content, wherein the first content may be greater than the second content, and the first content may be greater than the third content.

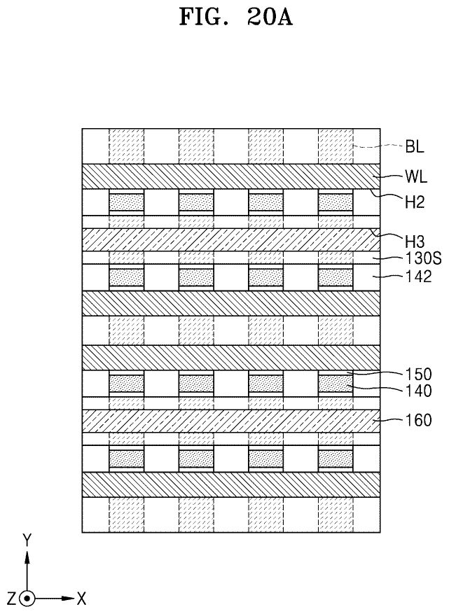

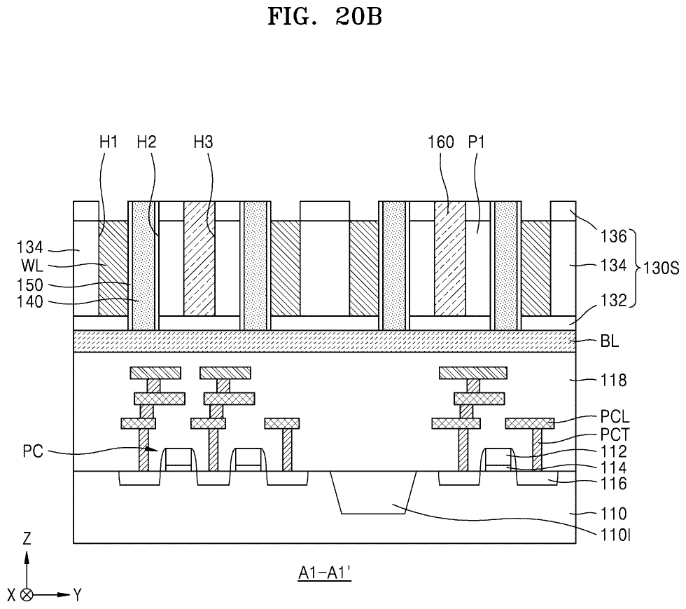

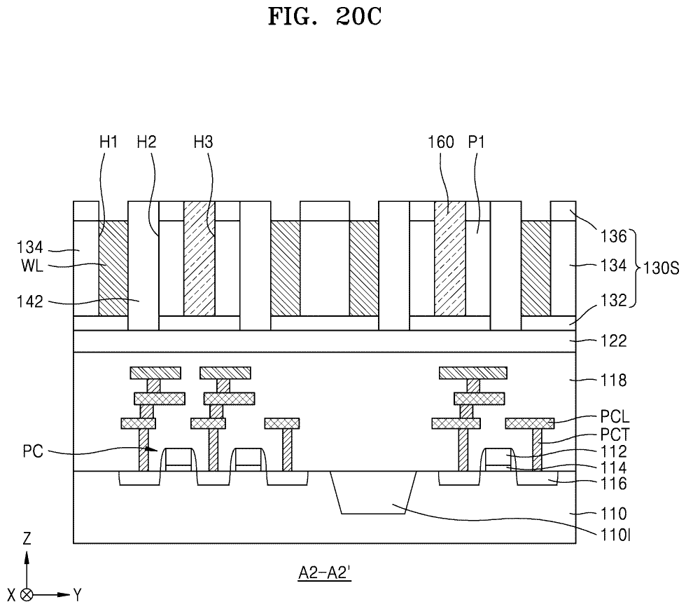

Referring to FIGS. 20A to 20C, a mask pattern may be formed on the mold stack 130S, and a portion of the channel layer 140 and a portion of the gate insulating layer 150 that are not covered by the mask pattern may be removed. After that, within the second opening H2, a buried insulating layer 142 may be formed in a portion from which the portion of the channel layer 140 and the portion of the gate insulating layer 150 have been removed.

As illustrated in FIG. 20A, the channel layer 140 may be located at a position corresponding to the bit line BL within one second opening H2, and the buried insulating layer 142 may be located between two adjacent channel layers 140 within the same second opening H2.

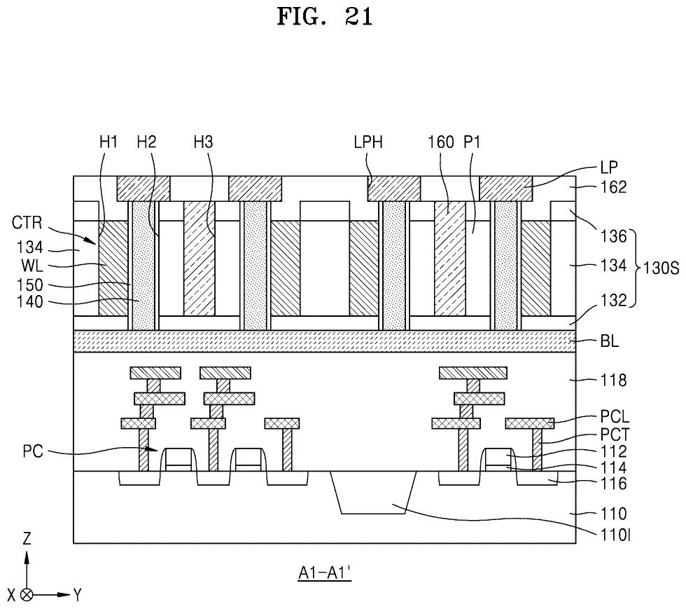

Referring to FIG. 21, an upper insulating layer 162 may be formed on the mold stack 130S. After that, landing pad openings LPH exposing an upper surface of the channel layer 140 may be formed by removing a portion of the upper insulating layer 162, and a landing pad LP may be formed within each of the landing pad openings LPH. In some embodiments, the landing pad LP may be formed of or include Ti, TiN, Ta, TaN, W, WN, TiSiN, WSiN, polysilicon, or a combination thereof.

Referring back to FIG. 3, a storage node SN may be formed on the landing pad LP.

The semiconductor device 100 may be completed by performing the process described above.

According to some embodiments, the channel layer 140 may include an oxide semiconductor in which fluorine is contained by diffusing/moving fluorine atoms included in the fluorine-containing insulating layer 160 into the channel layer 140 through the annealing process P210. Accordingly, trap density within the channel layer 140 may decrease, channel mobility may increase, or material stability of the channel layer 140 may improve. Therefore, electrical performance of a cell transistor CTR including the oxide semiconductor in which fluorine is contained as a composition of the channel layer 140 may improve.

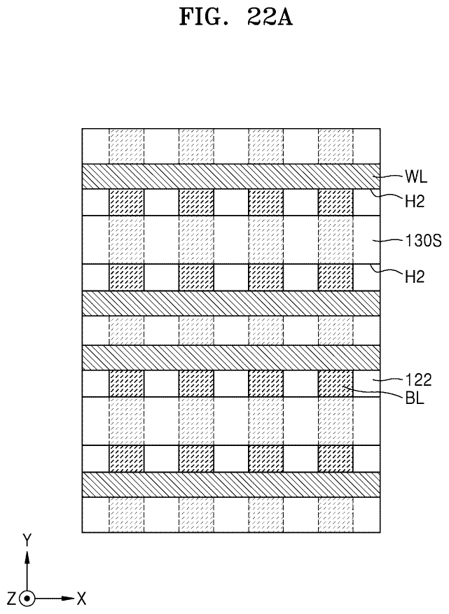

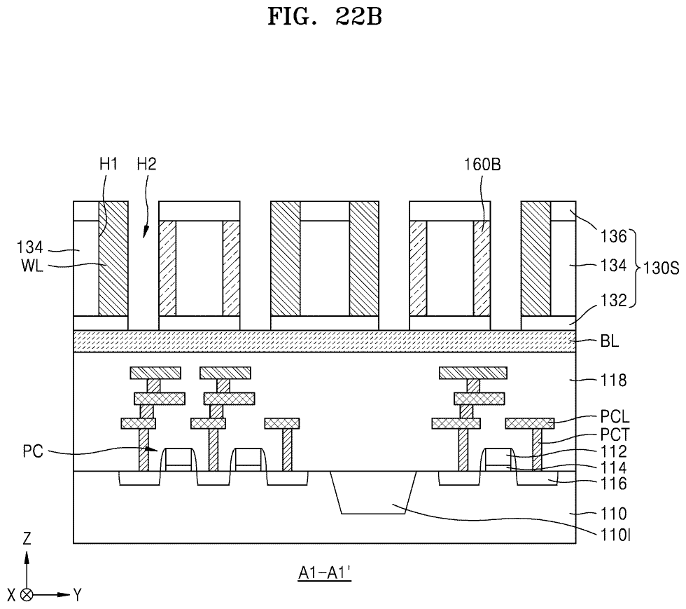

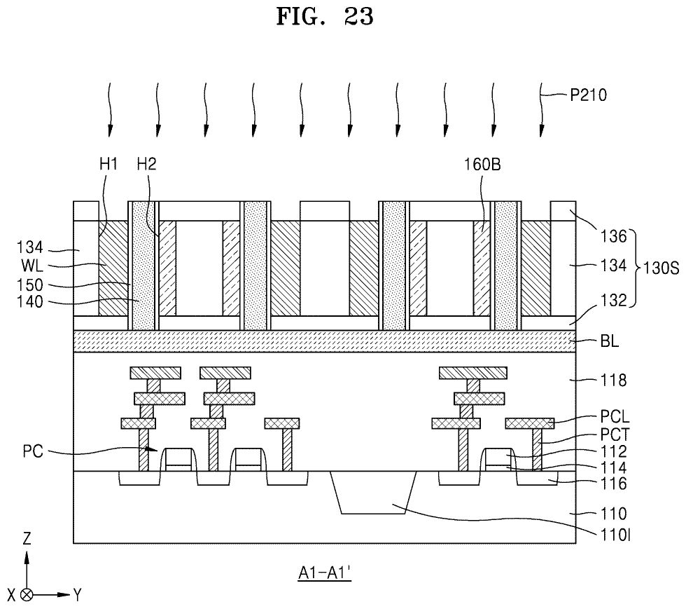

FIGS. 22A, 22B, and 23 are schematic views illustrating a method of manufacturing a semiconductor device 100B, according to embodiments.

First, a word line WL may be formed within a first opening H1 by performing the process described with reference to FIGS. 11A to 13B.

Referring to FIGS. 22A and 22B, a mask pattern (not shown) may be formed on a mold stack 130S, and a second opening H2 may be formed using the mask pattern as an etching mask. The second opening H2 may pass through all of a cover insulating layer 136, a mold insulating layer 134, and an etch stop film 132, and the second opening H2 may have a bottom portion exposing an upper surface of a bit line BL and an upper surface of a bit line separation insulating layer 122.

In some embodiments, a process of forming the second opening H2 may include an etching process using fluorine-containing etchants. For example, the process of forming the second opening H2 may be an etching process using fluorine-containing etchants in which at least one of tetrafluoromethane (CF₄), tetrafluoroethane (CF₃CH₂F), hexafluoroethane (C₂F₆), and sulfur hexafluoride (SF₆) is contained.

The second opening H2 may be formed to communicate with the first opening H1, and the second opening H2 may be formed to expose a side wall of the word line WL and extend in a first horizontal direction X. Accordingly, a first side wall of the second opening H2 may expose the word line WL, and a second side wall of the second opening H2 may expose the mold stack 130S (e.g., the etch stop film 132, the mold insulating layer 134, and the cover insulating layer 136).

In some embodiments, a fluorine-containing insulating layer 160B may be formed on the second side wall of the second opening H2 in an etching process using fluorine-containing etchants. In the etching process, fluorine may be accumulated in a portion of the mold insulating layer 134 adjacent to a side wall of the mold insulating layer 134 that is exposed to the fluorine-containing etchants, thereby allowing the fluorine-containing insulating layer 160B to be formed.

Referring to FIG. 23, the preliminary channel layer 140P (see FIG. 15B) and the gate insulating layer 150 may be formed within the second opening H2.

After that, an annealing process P210 may be performed.

In some embodiments, the annealing process P210 may be performed at a temperature of about 100° C. to about 400° C. for several minutes to several hours. In some embodiments, the annealing process P210 may be performed at atmospheric pressure or under reduced pressure. In some embodiments, by the annealing process P210, fluorine atoms contained in the fluorine-containing insulating layer 160B may diffuse and move into the preliminary channel layer 140P.

A channel layer 140 may be formed as the fluorine atoms diffuse into the preliminary channel layer 140P by the annealing process P210.

According to some embodiments, as the channel layer 140 includes an oxide semiconductor in which fluorine is contained, for example, an oxide semiconductor such as indium gallium zinc oxide containing fluorine, fluorine ions may bind to oxygen vacancies within the channel layer 140 and trap density within the channel layer 140 may decrease. Alternatively, as some oxygen atoms of the oxide semiconductor forming the channel layer 140 are replaced with fluorine atoms, channel mobility may increase. Alternatively, as a portion of a relatively weak bonding of zinc atoms and oxygen atoms of the channel layer 140 is replaced with a relatively strong bonding of zinc atoms and fluorine atoms, material stability of the channel layer 140 may improve.

In some embodiments, a fluorine content in the fluorine-containing insulating layer 160B may be a first content, and a fluorine content in the channel layer 140 may be a second content, wherein the first content may be greater than the second content.

After that, the semiconductor device 100B may be completed by performing the process described with reference to FIGS. 20A to 21.

According to some embodiments, fluorine atoms may accumulate in a portion of the mold insulating layer 134 that is exposed to the fluorine-containing etchants in a process of forming the second opening H2, thereby allowing the fluorine-containing insulating layer 160B to be formed, and the channel layer 140 including a fluorine-containing oxide semiconductor may be formed by diffusing/moving fluorine atoms included in the fluorine-containing insulating layer 160B into the channel layer 140 through the annealing process P210. Therefore, trap density within the channel layer 140 may decrease, channel mobility may increase, or material stability of the channel layer 140 may improve. Therefore, electrical performance of a cell transistor CTR including an oxide semiconductor in which fluorine is contained as a composition of the channel layer 140 may improve.

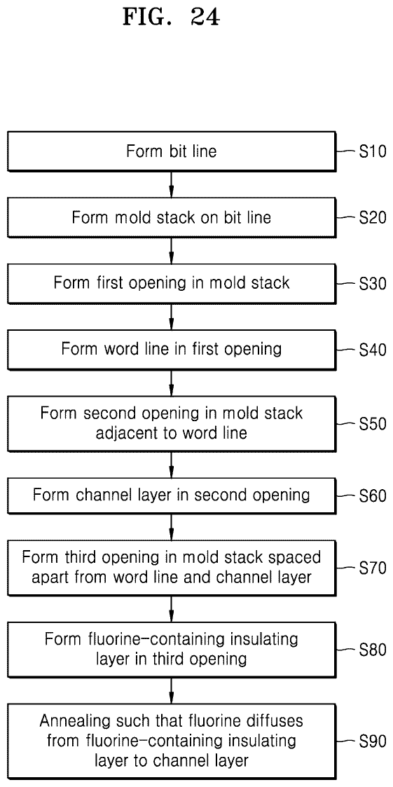

FIG. 24 shows a method of manufacturing a semiconductor device according to embodiments.

Referring to FIG. 24, a bit line BL may be formed (S10). The bit line BL may be formed on a peripheral circuit insulating layer 118 that is on a substrate 110.

At S20, a mold stack 130S may be formed on the bit line BL.

At S30, a first opening H1 may be formed in the mold stack 130S.

At S40, a word line WL may be formed in the first opening H1 that is formed in the mold stack 130S.

At S50, a second opening H2 may be formed in the mold stack 130S. The second opening H2 may be adjacent to the word line WL.

At S60, a channel layer 140 may be formed in the second opening H2 that is formed in the mold stack 130S.

At S70, a third opening H3 may be formed in the mold stack 130S. The third opening H3 may be spaced apart from the word line WL and from the channel layer 140.

At S80, a fluorine-containing insulating layer 160 may be formed in the third opening H3 that is formed in the mold stack 130S.

At S90, an annealing process may be performed such that fluorine diffuses from the fluorine-containing insulating layer 160 to the channel layer 140.

According to the inventive concept, by diffusing/moving fluorine atoms included in a fluorine-containing insulating layer into a channel layer through an annealing process, the channel layer may include an oxide semiconductor in which fluorine is contained. Accordingly, trap density within the channel layer may decrease, channel mobility may increase, or material stability of the channel layer may improve. Therefore, electrical performance of a cell transistor including the oxide semiconductor in which fluorine is contained as a composition of the channel layer may improve.

While the inventive concept has been particularly shown and described with reference to embodiments thereof, it will be understood that various changes in form and details may be made therein without departing from the spirit and scope of the inventive concept.

1. A semiconductor device comprising:
a bit line above a substrate and extending in a first horizontal direction;
a word line at a higher vertical level than the bit line and extending in a second horizontal direction crossing the first horizontal direction;
a fluorine-containing insulating layer spaced apart from the word line and extending in the second horizontal direction; and
a channel layer between the word line and the fluorine-containing insulating layer, the channel layer including a first side surface and a second side surface opposite to the first side surface, wherein the first side surface faces the word line,
wherein the channel layer includes an oxide semiconductor and fluorine.

2. The semiconductor device of claim 1, wherein the fluorine-containing insulating layer includes fluorine at a first amount,
the channel layer includes fluorine at a second amount, and
the second amount is less than the first amount.

3. The semiconductor device of claim 2, wherein the second amount is about 0.1 atomic percent (at %) to about 6 at %.

4. The semiconductor device of claim 1, further comprising:
a mold insulating layer above the bit line, a first portion of the mold insulating layer being between the channel layer and the fluorine-containing insulating layer and a second portion of the mold insulating layer being on a side wall of the word line; and
a gate insulating layer on the first side surface and the second side surface of the channel layer, a first portion of the gate insulating layer being between the first side surface of the channel layer and the word line and a second portion of the gate insulating layer being between the second side surface of the channel layer and the mold insulating layer.

5. The semiconductor device of claim 4, wherein the first portion of the mold insulating layer located between the fluorine-containing insulating layer and the channel layer includes fluorine.

6. The semiconductor device of claim 5, wherein the fluorine-containing insulating layer includes fluorine at a first amount,
the first portion of the mold insulating layer includes fluorine at a third amount, and
the third amount is less than the first amount.

7. The semiconductor device of claim 4, wherein the word line is in a first opening which passes through the mold insulating layer and extends in the first horizontal direction, and
the channel layer and the gate insulating layer are in a second opening which passes through the mold insulating layer and is adjacent to the word line.

8. The semiconductor device of claim 7, wherein the fluorine-containing insulating layer is in a third opening which passes through the mold insulating layer, is spaced apart from the first opening and the second opening, and extends in the first horizontal direction.

9. The semiconductor device of claim 1, wherein the fluorine-containing insulating layer includes silicon nitride doped with fluorine.

10. The semiconductor device of claim 1, further comprising:
a mold insulating layer, a first portion of the mold insulating layer being on a side wall of the word line and a second portion of the mold insulating layer being on a side wall of the fluorine-containing insulating layer above the bit line; and
a gate insulating layer located on the first side surface and the second side surface of the channel layer, a first portion of the gate insulating layer being between the first side surface of the channel layer and the word line and a second portion of the gate insulating layer being between the second side surface of the channel layer and the fluorine-containing insulating layer.

11. The semiconductor device of claim 10, wherein the fluorine-containing insulating layer includes silicon nitride doped with fluorine.

12. A semiconductor device comprising:
a bit line above a substrate and extending in a first horizontal direction;
an etch stop film on the bit line;
a mold insulating layer on the etch stop film;
a word line in a first opening that passes through the mold insulating layer and extends in the first horizontal direction;
a channel layer located in a second opening that is adjacent to the word line and passes through the mold insulating layer and the etch stop film; and
a fluorine-containing insulating layer spaced apart from the channel layer in a third opening that passes through the mold insulating layer, wherein the third opening extends in the first horizontal direction,
wherein the channel layer includes an oxide semiconductor and fluorine.

13. The semiconductor device of claim 12, wherein the mold insulating layer includes a first portion between the second opening and the third opening, and
the first portion of the mold insulating layer includes fluorine.

14. The semiconductor device of claim 13, further comprising a gate insulating layer in the second opening of the mold insulating layer, a first portion of the gate insulating layer being between the channel layer and the word line and a second portion of the gate insulating layer being between the channel layer and the first portion of the mold insulating layer.

15. The semiconductor device of claim 13, wherein the fluorine-containing insulating layer includes fluorine at a first amount,
the channel layer includes fluorine at a second amount, and
the second amount is less than the first amount.

16. The semiconductor device of claim 15, wherein the second amount is about 0.1 at % to about 6 at %.

17. The semiconductor device of claim 15, wherein the first portion of the mold insulating layer includes fluorine at a third amount, and
the third amount is less than the first amount.

18. The semiconductor device of claim 17, wherein the fluorine-containing insulating layer includes silicon nitride doped with fluorine,
the first portion of the mold insulating layer includes silicon oxide in which fluorine is contained,
the channel layer includes an oxide semiconductor doped with fluorine, and
the oxide semiconductor includes at least one of indium gallium zinc oxide (InₓGa_{y}Zn_{z}O), indium tungsten oxide (InₓW_{y}O), indium tin gallium oxide (InₓSn_{y}Ga_{z}O), indium aluminum zinc oxide (InₓAl_{y}Zn_{z}O), indium gallium oxide (InₓGa_{y}O), indium tin zinc oxide (InₓSn_{y}Zn_{z}O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn_{z}O), zinc tin oxide (ZnₓSn_{y}O), zirconium zinc tin oxide (ZrₓZn_{y}Sn_{z}O), gallium zinc tin oxide (GaₓZn_{y}Sn_{z}O), aluminum zinc tin oxide (AlₓZn_{y}Sn_{z}O), and tin oxide (SnₓO).

19. A semiconductor device comprising:
a peripheral circuit region above a substrate;
a bit line in the peripheral circuit region and extending in a first horizontal direction;
an etch stop film on the bit line;
a mold insulating layer on the etch stop film;
a word line in a first opening that passes through the mold insulating layer and extends in the first horizontal direction;
a channel layer in a second opening that is adjacent to the word line and passes through the mold insulating layer and the etch stop film, the channel layer including an oxide semiconductor and fluorine;
a fluorine-containing insulating layer spaced apart from the channel layer in a third opening that passes through the mold insulating layer, wherein the third opening extends in the first horizontal direction;
a gate insulating layer in the second opening of the mold insulating layer, a first portion of the gate insulating layer being between the channel layer and the word line and a second portion of the gate insulating layer being between the channel layer and the mold insulating layer; and
a storage node above the channel layer.

20. The semiconductor device of claim 19, wherein the fluorine-containing insulating layer includes fluorine at a first amount,
the channel layer includes fluorine at a second amount which is less than the first amount, and
the second amount is about 0.1 at % to about 6 at %.

21. (canceled)
